(19) United States
(12) Patent Application Publication
(10) Pub. No.: US 2020/0278726 A1
(43) Pub. Date: Sep. 3, 2020

(54) POWER SUPPLY FAN

(71) Applicant: HEWLETT PACKARD ENTERPRISE DEVELOPMENT LP, Houston, TX (US)

(72) Inventors: Rameez Kadar Kazi, Houston, TX (US); Atluri R. Prasad, Houston, TX (US); Michael R. Miller, Houston, TX (US)

(21) Appl. No.: 16/063,758

(22) PCT Filed: Jan. 8, 2016
(86) PCT No.: PCT/US2016/012706

§ 371 Date: Jun. 19, 2018

(51) Int. Cl. G06F 1/20; G06F 1/26; H05K 7/20

(52) U.S. Cl. CPC G06F 1/20; H05K 7/20136; H05K 7/20836; G06F 1/26

(57) ABSTRACT

In one example, a system for a power supply fan includes a power supply coupled to a computing system, a modular fan coupled to the power supply, and a system board of the computing system coupled to the modular fan.

### BACKGROUND

Computing systems can utilize a number of power supplies. Power supplies can include electronic devices that convert a first type of electrical energy to a second type of electrical energy. In some examples, the power supplies for a computing system can be manufactured by different companies with different configurations. In some examples, the power supplies can utilize different cooling systems and methods.

### BRIEF DESCRIPTION OF THE DRAWINGS

FIG. 1 illustrates a diagram of an example of a system for a power supply fan consistent with the present disclosure.

FIG. 2 illustrates a diagram of an example of a system for a power supply fan consistent with the present disclosure.

FIG. 3 illustrates a diagram of an example of a system for a power supply fan consistent with the present disclosure.

FIG. 4 illustrates a diagram of an example computing device for a power supply fan consistent with the present disclosure.

### DETAILED DESCRIPTION

A number of examples for a power supply fan are described herein. In one example, a system for a power supply fan includes a power supply coupled to a computing system, a modular fan coupled to the power supply, and a system board of the computing system coupled to the modular fan. In another example, a system for a power supply fan includes a first power supply coupled to a computing system, a first modular fan coupled to the first power supply, a second power supply coupled to the computing system, a second modular fan coupled to the second power supply, and a system board of the computing system coupled to the first modular fan and to the second modular fan. Furthermore, in another example, a system for a power supply fan includes a plurality of fanless power supplies coupled to a computing system, a plurality of modular fans each coupled to a fanless power supply of the plurality of fanless power supplies, and a system board coupled to the plurality of modular fans.

The power supply fan systems described herein can utilize a number of modular fans to cool a number of power supplies. In some examples, the number of power supplies can be fanless power supplies. For example, the number of power supplies can have an internal fan removed from the power supply. In some examples, the removed internal fan can be replaced with a receiving bay for a modular fan. In some examples, the receiving bay can be utilized to couple a modular fan to a power supply.

In some examples, the number of power supplies can be coupled to a computing system. For example, the number of power supplies can be electrically coupled to a number of computing devices (e.g., servers, etc.) within an enclosure (e.g., server blade enclosure, etc.). In some examples, the number of power supplies can be utilized to provide power to the number of computing devices within the enclosure. For example, the number of power supplies can convert input power to power that can be utilized by the number of computing devices.

In some examples, the number of modular fans can be coupled to a system board of the computing system. In some examples, the system board can include a computing device or controller to manage (e.g., control functionality, etc.) of the number of modular fans. In some examples, the system board can provide a number of managing functions for the enclosure. For example, the system board can manage power and cooling resources for the enclosure. In some examples, the system board of the computing system can be separate from the power supply.

Previous systems utilized power supplies with integrated fans that were managed and controlled by the power supplies. These systems can provide inconsistent cooling resources between a plurality of power supplies within an enclosure. The power supply fan systems described herein can provide consistent cooling between the plurality of power supplies as well as providing a modular cooling system for the plurality of power supplies.

The figures herein follow a numbering convention in which the first digit corresponds to the drawing figure number and the remaining digits identify an element or component in the drawing. Elements shown in the various figures herein may be capable of being added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense.

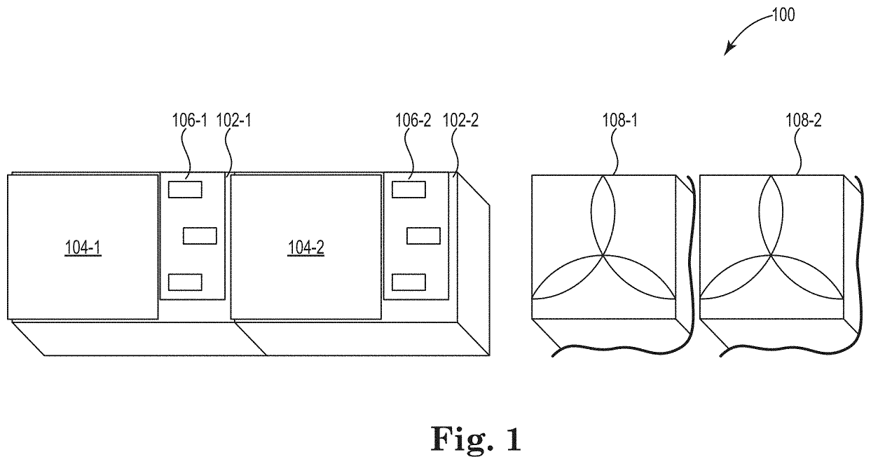

FIG. 1 illustrates a diagram of an example of a system 100 for a power supply fan consistent with the present disclosure. The system 100 can include a number of power supplies 102-1, 102-2 with corresponding electrical connections 106-1, 106-2 and a number of modular fans 108-1, 108-2.

In some examples, the number of power supplies 102-1, 102-2 can be utilized to convert input power to power that can be utilized by a computing device. For example, the number of power supplies 102-1, 102-2 can receive alternating current (AC) power from an input and send direct current (DC) to a number of computing devices of a computing system. In some examples, the number of power supplies 102-1, 102-2 can receive input power via the number of electrical connections 106-1, 106-2. In some examples, the number of power supplies 102-1, 102-2 can send power to a number of computing devices via the number of electrical connections 106-1, 106-2.

In some examples, the number of power supplies 102-1, 102-2 can be fanless power supplies. For example, the number of power supplies 102-1, 102-2 can have no integrated fan (e.g., internal fan, etc.) controlled by the number of power supplies 102-1, 102-2. In some examples, an integrated fan of the number of power supplies 102-1, 102-2 can be removed.

In some examples, the number of power supplies 102-1, 102-2 can include a number of receiving bays 104-1, 104-2. In some examples, the number of receiving bays 104-1, 104-2 can replace a removed integrated fan for the number of power supplies 102-1, 102-2. In some examples, the number of receiving bays 104-1, 104-2 can be utilized to receive the number of modular fans 108-1, 108-2. For example, the number of receiving bays 104-1, 104-2 can include a bracket to receive the number of module fans 108-1, 108-2. In some examples, the number of receiving bays 104-1, 104-2 can include a locking mechanism to secure the number of modular fans 108-1, 108-2 in the number of receiving bays 104-1, 104-2.

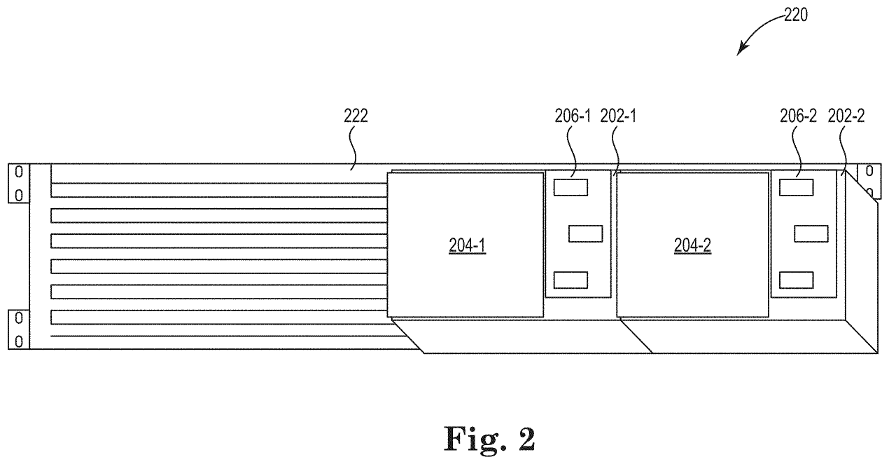

FIG. 2 illustrates a diagram of an example of a system 220 for a power supply fan consistent with the present disclosure. The system 220 can include a number of power supplies 202-1, 202-2 coupled to a system chassis 222. The system chassis 222 can include a rail or mounting chassis of an enclosure (e.g., server enclosure, server blade enclosure, etc.).

In some examples, the number of power supplies 202-1, 202-2 can receive input power via the number of electrical connections 206-1, 206-2. In some examples, the number of power supplies 202-1, 202-2 can send power to a number of computing devices within the enclosure via the number of electrical connections 206-1, 206-2. In some examples, the number of power supplies 202-1, 202-2 can receive power from an external power source via the number of electrical connections 206-1, 206-2 to provide power to the number of computing devices within the enclosure.

In some examples, the number of power supplies 202-1, 202-2 can be fanless power supplies. In some examples, the number of power supplies 202-1, 202-2 can have an internal fan removed. For example, the number of power supplies 202-1, 202-2 can have factory fan (e.g., fan provided by a manufacturer, etc.) that is internal to a power supply enclosure. In this example, the factory fan can be removed from the power supply enclosure to produce a fanless power supply.

In some examples, the removal of the factory fan can provide space for a number of receiving bays 204-1, 204-2. The number of receiving bays 204-1, 204-2 can include a number of brackets for a modular fan to couple to the number of receiving bays 204-1, 204-2. As described herein, the number of receiving bays 204-1, 204-2 can be utilized to couple modular fans that can be centrally controlled by a computing device such as a system board. In some examples, the computing device can be utilized to control cooling resources for the enclosure. That is, the computing device can include modules with instructions to control cooling resources for the number of power supplies 202-1, 202-2 and the computing devices within the enclosure.

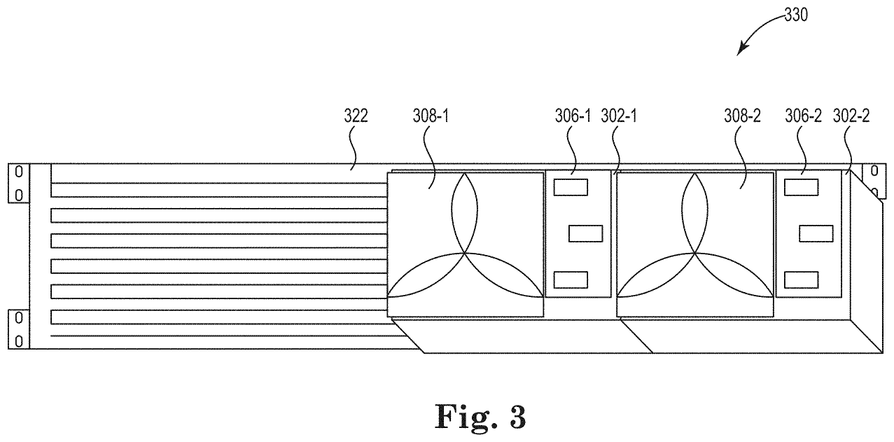

FIG. 3 illustrates a diagram of an example of a system 330 for a power supply fan consistent with the present disclosure. The system 330 can be similar to system 220 with a number of modular fans 308-1, 308-2 installed within the number of receiving bays (e.g., receiving bays 204-1, 204-2 as referenced in FIG. 2, etc.).

In some examples, the number of power supplies 302-1, 302-2 can receive input power via the number of electrical connections 306-1, 306-2. In some examples, the number of power supplies 302-1, 302-2 can send power to a number of computing devices within the enclosure via the number of electrical connections 306-1, 306-2. In some examples, the number of power supplies 302-1, 302-2 can receive power from an external power source via the number of electrical connections 306-1, 306-2 to provide power to the number of computing devices within the enclosure.

The system 330 can include a number of power supplies 302-1, 302-2 coupled to a system chassis 322. The system chassis 322 can include a rail or mounting chassis of an enclosure (e.g., server enclosure, server blade enclosure, etc.). As described herein, the number of modular fans 308-1, 308-2 can be coupled to a system board of the enclosure. As described herein, the computing device can be utilized to control cooling resources for the enclosure. That is, the computing device can include modules (e.g., controller module 448, etc.) with instructions to control cooling resources for the number of power supplies 302-1, 302-2 and the computing devices within the enclosure.

In some examples, the system board of the enclosure can be separate and distinct from the number of power supplies 302-1, 302-2. In some examples, the system board can be coupled to a temperature sensor. In some examples, the temperature sensor can be utilized to determine temperature data for the enclosure. In some examples, the temperature data can be utilized to cool computing components of computing devices within the enclosure. In some examples, the system board can control the functionality (e.g., activate, deactivate, fan speed, etc.) of the modular fans 308-1, 308-2 based on the temperature data for the enclosure. In some examples, utilizing the system board can synchronize the functionality of the number of modular fans 308-1, 308-2 based on the temperature data received by the temperature sensor.

In some examples, the number of modular fans 308-1, 308-2 can be controlled by the same computing device as a plurality of other cooling devices within the enclosure. For example, the number of modular fans 308-1, 308-2 can be controlled by a central computing device that includes instructions for cooling computing devices within the enclosure. In some examples, the computing device can be utilized to control a number of additional fans for cooling memory and/or processing devices. In some examples, the number of additional fans throughout the enclosure can be the same type of modular fans as the number of modular fans 308-1, 308-2.

A cost of cooling devices can be reduced by utilizing the same type of fans throughout the enclosure since the modular fans 308-1, 308-2 can be detachable from the number of power supplies 302-1, 302-2 and utilized throughout the enclosure. In some examples, the modular fans 308-1, 308-2 can be interchangeable with the number of power supplies 302-1,302-2. For example, modular fan 308-1 can be utilized with power supply 302-1 or power supply 302-2.

In addition, utilizing a single computing device for cooling the number of power supplies 302-1, 302-2 and cooling computing devices within the enclosure can provide more consistent cooling throughout the enclosure. Furthermore, utilizing the same computing device to control the number of modular fans 308-1, 308-2 can provide more consistent cooling of the number of power supplies 302-1, 302-2.

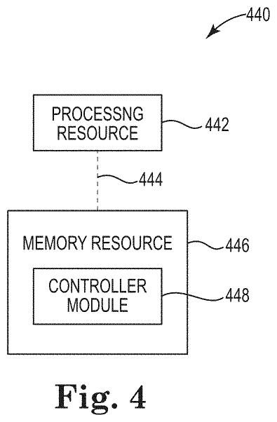

FIG. 4 illustrates a diagram of an example computing device 440 consistent with the present disclosure. The computing device 440 can utilize software, hardware, firmware, and/or logic to perform functions described herein.

The computing device 440 can be any combination of hardware and program instructions configured to share information. The hardware, for example, can include a processing resource 442 and/or a memory resource 446 (e.g., computer-readable medium (CRM), machine readable medium (MRM), database, etc.). A processing resource 442, as used herein, can include any number of processors capable of executing instructions stored by a memory resource 446. Processing resource 442 may be implemented in a single device or distributed across multiple devices. The program instructions (e.g., computer readable instructions (CRI)) can include instructions stored on the memory resource 446 and executable by the processing resource 442 to implement a function (e.g., control a number of fans, activate fans, deactivate fans, control cooling resources, etc.).

The memory resource 446 can be in communication with a processing resource 442. A memory resource 446, as used herein, can include any number of memory components capable of storing instructions that can be executed by processing resource 442. Such memory resource 446 can be a non-transitory CRM or MRM. Memory resource 446 may be integrated in a single device or distributed across multiple devices. Further, memory resource 446 may be fully or partially integrated in the same device as processing resource 442 or it may be separate but accessible to that device and processing resource 442. Thus, it is noted that the computing device 214 may be implemented on a participant device, on a server device, on a collection of server devices, and/or a combination of the participant device and the server device.

The memory resource 446 can be in communication with the processing resource 442 via a communication link (e.g., a path) 444. The communication link 444 can be local or remote to a machine (e.g., a computing device) associated with the processing resource 442. Examples of a local communication link 444 can include an electronic bus internal to a machine (e.g., a computing device) where the memory resource 446 is one of volatile, non-volatile, fixed, and/or removable storage medium in communication with the processing resource 442 via the electronic bus.

A number of modules (e.g., controller module 448) can include CRI that when executed by the processing resource 442 can perform functions. The number of modules (e.g., controller module 448) can be sub-modules of other modules. In another example, the number of modules (e.g., controller module 448) can comprise individual modules at separate and distinct locations (e.g., CRM, etc.).

As used herein, “logic” is an alternative or additional processing resource to perform a particular action and/or function, etc., described herein, which includes hardware, e.g., various forms of transistor logic, application specific integrated circuits (ASICs), etc., as opposed to computer executable instructions, e.g., software firmware, etc., stored in memory and executable by a processor. Further, as used herein, “a” or “a number of” something can refer to one or more such things. For example, “a number of widgets” can refer to one or more widgets.

The above specification, examples and data provide a description of the method and applications, and use of the system and method of the present disclosure. Since many examples can be made without departing from the spirit and scope of the system and method of the present disclosure, this specification merely sets forth some of the many possible example configurations and implementations.

What is claimed:

1. A system for a power supply fan, comprising:
a power supply coupled to a computing system;
a modular fan coupled to the power supply; and
a system board of the computing system coupled to the modular fan.

2. The system of claim 1, wherein the system board of the computing system is separate from the power supply.

3. The system of claim 1, wherein the modular fan is controlled by the system board.

4. The system of claim 1, wherein the modular fan is detachable from the power supply.

5. The system of claim 1, comprising a temperature sensor coupled to the system board of the computing system.

6. The system of claim 5, wherein the system board of the computing system activates and deactivates the modular fan based on data received from the temperature sensor.

7. The system of claim 1, wherein the system board of the computing system controls other cooling functions of the computing system.

8. A system for a power supply fan, comprising:
a first power supply coupled to a computing system;
a first modular fan coupled to the first power supply;
a second power supply coupled to the computing system;
a second modular fan coupled to the second power supply; and
a system board of the computing system coupled to the first modular fan and to the second modular fan.

9. The system of claim 8, wherein the system board controls the first modular fan and the second modular fan independent of the first power supply and second power supply.

10. The system of claim 8, wherein the system board of the computing system synchronizes a fan speed of the first modular fan and the second modular fan.

11. The system of claim 8, comprising a temperature sensor coupled to the system board of the computing system, wherein the system board of the computing system controls the first modular fan and the second modular fan based on data received from the temperature sensor.

12. A system for a power supply fan, comprising:
a plurality of fanless power supplies coupled to a computing system;
a plurality of modular fans each coupled to a fanless power supply of the plurality of fanless power supplies; and
a system board coupled to the plurality of modular fans.

13. The system of claim 12, wherein the plurality of modular fans comprise a single type of modular fan.

14. The system of claim 12, wherein the plurality of modular fans are interchangeable with the plurality of fanless power supplies.

15. The system of claim 12, wherein the plurality of modular fans are each coupled to a chassis of the computing system.
